(19) United States
(12) Patent Application Publication
(10) Pub. No.: US 2007/0018237 A1
(43) Pub. Date: Jan. 25, 2007

(54) Non-volatile memory device having fin-type channel region and method of fabricating the same

(75) Inventors: Won-Joo Kim, Suwon-si (KR); Suk-Pil Kim, Yongin-si (KR); Yoon-Dong Park, Yongin-si (KR); Eun-Hong Lee, Anyang-si (KR); Jae-Woong Hyun, Uijeongbu-si (KR); Sung-Jae Byun, Seongnam-si (KR); Jung-Hoon Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/489,445

(22) Filed: Jul. 20, 2006

(30) Foreign Application Priority Data
Jul. 22, 2005 (KR) 10-2005-0066988

(51) Int. Cl. H01L 29/792

(52) U.S. Cl. 257/324

(57) ABSTRACT

A non-volatile memory device with improved integration and/or improved performance by reducing an area per bit and controlling a body bias, and a method of fabricating the same. The non-volatile memory device may use surface portions of the outer side surfaces and/or the upper surfaces of at least one pair of fins protruding from a body and extending, spaced from each other along one direction, as at least one pair of channel regions. At least one control gate electrode may be formed across the channel regions, and at least one pair of storage nodes may be interposed in at least one portion between the control gate electrode and the channel regions.

### PRIORITY STATEMENT

This application claims the benefit of Korean Patent Application No. 10-2005-0066988, filed on Jul. 22, 2005, in the Korean Intellectual Property Office, the disclosure of which is incorporated herein in its entirety by reference.

### BACKGROUND OF THE INVENTION

1. Field of the Invention

Example embodiments of the present invention relate to a non-volatile memory device, and more particularly, to a non-volatile memory device having a fin-type channel region, and a method of fabricating the same. For example, the non-volatile memory device of example embodiments of the present invention may include a flash memory and/or a Semiconductor Oxide Nitride Oxide Semiconductor (SONOS) memory.

2. Description of the Related Art

A non-volatile memory device, for example, flash memory may have a conductive floating gate electrode interposed between a control gate electrode and a semiconductor substrate. The floating gate electrode may be used as a storage node for storing charge. The flash memory may read out whether a conductive channel region is formed in the semiconductor substrate, depending on whether a threshold voltage of the semiconductor substrate has changed in accordance with charge accumulation of the floating gate electrode. Another non-volatile memory device, for example, SONOS memory may have a charge trap type storage node interposed between a control gate electrode and a semiconductor substrate. SONOS memory may operate in a similar way to the flash memory.

However, in non-volatile memory devices, an integration density and/or speed of the memory devices may be limited due to limitations of fine processing technology to define fine line width. Thus, efforts to increase memory capacity and/or memory speed are ongoing in addition to efforts to improve fine processing technology to achieve a narrower line width.

For example, conventional art discloses a Fin-FET and a Fin memory cell. A Fin-FET may use the upper surface and the side surfaces of a fin as a channel region. Thus, a Fin-FET may have a larger area channel region than that of a planar-type transistor, to provide a higher current flow. As a result, a Fin-FET may provide higher performance than that of the planar-type transistor.

However, because a conventional Fin-FET may be fabricated using an SOI (Silicon On Insulator) substrate, the fin may float in relation to a semiconductor body. As a result, a threshold voltage of a transistor using a body bias may be difficult to control, and therefore, a threshold voltage of a CMOS transistor may be difficult to control. Further, because a conventional fin memory cell may use an area of at least 2 F×2 F based on 1 F of a gate length in order to provide 2-bit operation, an area per bit may be 2 F², which is relatively large. As a result, an integration density of the fin memory cell may be limited.

### SUMMARY OF THE INVENTION

Example embodiments of the present invention provide a non-volatile memory device having higher integration and/or having higher performance by reducing an area per bit and/or controlling a body bias.

Example embodiments of the present invention also provide a method of fabricating the non-volatile memory device. Example embodiments of the present invention are directed to a non-volatile memory device including a semiconductor substrate including a body and at least one pair of fins formed from and protruding from the body and extending along one direction spaced from each other.

In an example embodiment, the at least one pair of fins do not float in relation to the body.

In an example embodiment, the non-volatile memory device may be a flash memory.

In an example embodiment, the non-volatile memory device may be a Semiconductor Oxide Nitride Oxide Semiconductor (SONOS) memory.

In an example embodiment, the non-volatile memory device may have a NAND structure.

In an example embodiment, the non-volatile memory device may have a NOR structure.

In an example embodiment, the non-volatile memory device may further include at least one pair of channel regions formed around surfaces of at least upper portions of outer side surfaces of the at least one pair of fins and upper surfaces of the at least one pair of fins, at least one control gate electrode extending along a direction different from the one direction, and insulated from the semiconductor substrate, and at least one pair of storage nodes interposed between the at least one control gate electrode and the at least one pair of channel regions formed on the upper portions of the outer side surfaces of the at least one pair of fins.

In an example embodiment, the at least one pair of storage nodes may include polysilicon, silicon germanium, silicon or metal dot, nano crystal, or a silicon nitride layer.

In an example embodiment, a gate length of the at least one control gate electrodes along the one direction may be 1 F and a width of each fin of the at least one pair of fins along the different direction may be 0.25 F.

In an example embodiment, the at least one pair of fins may operate as bit lines and the at least one control gate electrode may operate as a word line.

In an example embodiment, the non-volatile memory device may further include a first insulating layer formed on the body and burying portions between the at least one pair of fins, and at least one pair of source and drain regions spaced from each other along the one direction, and formed in the at least one pair of fins, wherein the at least one pair of channel regions may be disposed between the at least one pair of source and drain regions, and a second insulating layer formed on the at least one pair of channel regions, wherein the at least one control gate electrode extends across the first insulating layer and the second insulating layer.

In an example embodiment, the non-volatile memory device may further include a third insulating layer formed to expose lower portions of the outer side surfaces of the at least one pair of fins, and upper portions of the outer side surfaces of the at least one pair of fins on the body, and insulating the body and the control gate electrode.

In an example embodiment, a width of the first insulating layer along the different direction may be 1 F.

In an example embodiment, the first insulating layer may include a silicon oxide layer.

In an example embodiment, the at least one pair of fins may operate as at least one pair of bit lines, and the non-volatile memory device may further include a first insulating layer burying portions between the at least one pair of fins and the body to insulate the at least one pair of bit lines, a plurality of word lines, extending across the at least one pair of fins and spaced from each other along the one direction, composed of a plurality of control gate electrodes, insulated from the semiconductor substrate, a second insulating layer interposed between the plurality of word lines and the at least one pair of fins, and at least one pair of storage nodes interposed between the plurality of word lines and at least a portion of the second insulating layer.

In an example embodiment, a gate length of the plurality of control gate electrodes along the one direction may be 1 F, and a width of each fin of the at least one pair of fins along a different direction may be 0.25 F.

In an example embodiment, a width of the first insulating layer along a different direction may be 1 F.

In an example embodiment, a separation distance between each of the plurality of control gate electrodes along the one direction may be 1 F.

In an example embodiment, the at least one pair of storage nodes may include polysilicon, silicon germanium, a silicon or metal dot, a nano crystal, or a silicon nitride layer.

In an example embodiment, the first insulating layer may include a silicon oxide layer.

Example embodiments of the present invention are directed to a method of fabricating a non-volatile memory device including forming at least one pair of fins from a semiconductor substrate including a body, protruding from the body and extending along one direction spaced from each other.

In an example embodiment, the at least one pair of fins do not float in relation to the body.

In an example embodiment, the non-volatile memory device may be a flash memory.

In an example embodiment, the non-volatile memory device may be a Semiconductor Oxide Nitride Oxide Semiconductor (SONOS) memory.

In an example embodiment, the non-volatile memory device may have a NAND structure.

In an example embodiment, the non-volatile memory device may have a NOR structure.

In an example embodiment, forming the at least one pair of fins may further include forming a first insulating layer pattern on the semiconductor substrate, forming a second insulating layer spacer on sidewalls of the first insulating layer pattern, etching the semiconductor substrate using the first insulating layer pattern and the second insulating layer spacer as etch protecting mask, thereby forming a first trench, forming a first photoresist pattern in the first trench and extending over the semiconductor substrate in at least two directions by a given width, etching the semiconductor substrate using the first photoresist pattern as an etch protecting mask, thereby forming a second trench, and removing the first photoresist pattern, thereby forming the at least one pair of fins defined by the first and second trenches and protruding from the semiconductor substrate.

In an example embodiment, a width of the first trench may be 0.5 F and a width of the second trench may be 1 F.

In an example embodiment, a width of each fin of the at least one pair of fins may be 0.25 F.

In an example embodiment, forming the non-volatile memory device may further include forming a third insulating layer in the first and second trenches defining the at least one pair of fins, selectively etching the third insulating layer in the second trench, thereby exposing outer side surfaces of the at least one pair of fins surrounding the third insulating layer in the first trench, forming a gate insulating layer on exposed outer side surfaces and upper surfaces of the at least one pair of fins surrounding the third insulating layer, forming storage nodes on sidewalls of the gate insulating layer formed on the exposed outer side surfaces of the at least one pair of fins, and forming a control gate electrode across the at least one pair of fins and the third insulating layer on the resultant structure having the storage nodes.

In an example embodiment, etching the third insulating layer may include forming a second photoresist pattern on the third insulating layer in the fins and the first trench and etching the third insulating layer in the second trench, using the second photoresist pattern as an etch protecting mask.

In an example embodiment, a gate length of the control gate electrode may be 1 F, a width of the first trench may be 0.5 F, and a width of the second trench may be 1 F.

In an example embodiment, the storage nodes may include polysilicon, silicon germanium, silicon or metal dot, nano crystal, or a silicon nitride layer.

In an example embodiment, the third insulating layer may include a silicon oxide layer.

### BRIEF DESCRIPTION OF THE DRAWINGS

The above and other features and advantages will become more apparent by describing in detail example embodiments thereof with reference to the attached drawings in which:

FIG. 1 is a perspective view illustrating a non-volatile memory device according to an example embodiment of the present invention;

FIG. 2A is a cross-sectional view taken along a line of I-I′ of the non-volatile memory device of FIG. 1;

FIG. 2B is a cross-sectional view taken along a line of II-II′ of the non-volatile memory device of FIG. 1;

FIG. 3 is a schematic view illustrating a circuit layout of a NAND structure of a non-volatile memory device according to an example embodiment of the present invention; and

FIGS. 4 through 11 are sectional views illustrating a method of fabricating a non-volatile memory device according to an example embodiment of the present invention.

### DETAILED DESCRIPTION OF EXAMPLE EMBODIMENTS OF THE INVENTION

The present invention will now be described more fully hereinafter with reference to the accompanying drawings, in which example embodiments of the invention are shown. This invention may, however, be embodied in many different forms and should not be construed as being limited to the embodiments set forth herein. Rather, these example embodiments are provided so that this disclosure will be thorough and complete, and will fully convey the scope of the invention to those skilled in the art. Like numbers refer to like elements throughout the specification.

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

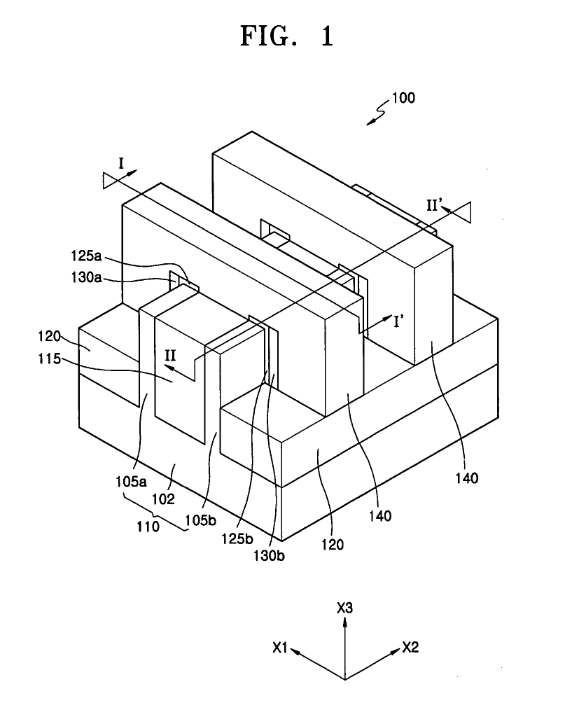

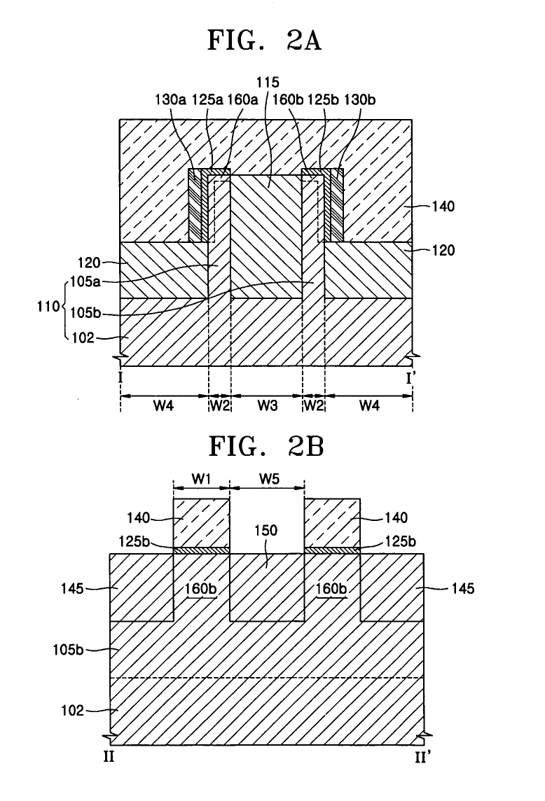

FIG. 1 is a perspective view illustrating a non-volatile memory device 100 according to an example embodiment of the present invention. FIG. 2A is a cross-sectional view taken along a line of I-I′ of the non-volatile memory device 100 of FIG. 1 and FIG. 2B is a cross-sectional view taken along a line of II-II′ of the non-volatile memory device 100 of FIG. 1.

Referring to FIGS. 1, 2A and 2B, the non-volatile memory device 100 may include channel regions 160a, 160b formed in two or more fins 105a, 105b, and a plurality of control gate electrodes 140 across the fins 105a, 105b, for example, substantially perpendicular. A pair of storage nodes 130a, 130b may be interposed between the channel regions 160a, 160b and the control gate electrodes 140.

In example embodiments, the non-volatile memory device 100 may be a flash memory or a SONOS memory. Example embodiments of non-volatile memory devices need not be defined by terminology, but rather by structure.

The semiconductor substrate 110 may include a body 102 and two or more fins 105a, 105b protruding from the body 102 and spaced from each other. For example, the fins 105a, 105b may be spaced from each other in the direction of X1, and may extend along the direction of X2. The semiconductor substrate 110 may be bulk silicon, bulk silicon-germanium, or a composite structure including silicon or silicon-germanium epitaxial layer formed on the bulk silicon or the bulk silicon-germanium. That is, the fins 105a, 105b may be composed of the same material as that of the body 102, or may be an epitaxial layer formed on the body 102. A pair of fins 105a, 105b is illustrated in the drawing, but a plurality of fins may be aligned along the direction of X1.

A buried insulating layer 115 may be buried between the pair of fins 105a, 105b. The buried insulating layer 115 may insulate the inner side walls of the fins 105a, 105b. An isolation layer 120 may be formed on the outer side surfaces of the fins 105a, 105b with a desired or predetermined depth from the body 102. That is, the isolation layer 120 may cover lower portions of the outer side surfaces of the fins 105a, 105b, but exposes the upper portions of the outer side surfaces of the fins 105a, 105b. The buried insulating layer 115 and the isolation layer 120 may isolate the fins 105a, 105b and device elements, but the names of the elements in example embodiments are not limited to specific devices. For example, the buried insulating layer 115 and the isolation layer 120 may include a silicon oxide layer having sufficient insulation and/or burial characteristics.

Based on the direction of X1, a silicon on insulator (SOI) structure may be formed, in which the buried insulating layer 115, one of the fins 105a, 105b, and the control gate electrode 140 are sequentially stacked. However, the structure of example embodiments may be different from a typical SOI structure, in which an active region floats in relation to a semiconductor body, by the fact that the fins 105a, 105b are connected to the body 102 along the direction of X3. Thus, the structure of the semiconductor substrate 110 in example embodiments of the present invention may be referred to as an SOI-like structure, and additional characteristics will be explained below.

Gate insulating layers 125a, 125b may be formed on one or more outer side surfaces and one or more upper surfaces of the fins 105a, 105b, respectively. The gate insulating layers 125a, 125b may be referred to as tunneling insulating layers because they may act as tunneling paths of charges. For example, the gate insulating layers 125a, 125b may be formed of a silicon oxide layer, a silicon nitride layer, a high-k dielectric layer, or a combination thereof.

Storage nodes 130a, 130b may be interposed at least partially between the gate insulating layers 125a, 125b and the control gate electrode 140, respectively. For example, the storage nodes 130a, 130b may be formed on the sidewalls of one ore more outer side surfaces of the fins 105a, 105b, and may not be formed on the upper surfaces of the fins 105a, 105b (or vice versa). This may be because the upper surfaces of the fins 105a, 105b are smaller in area than the side surfaces thereof.

The storage nodes 130a, 130b may be formed to include polysilicon, silicon germanium, silicon or metal dot, nano crystal, a silicon nitride layer, or a combination thereof. For example, the storage nodes 130a, 130b composed of polysilicon or silicon germanium may be used as a floating charge storage layer. As another example, the storage nodes 130a, 130b composed of silicon or metal dot, nano crystal, or a silicon nitride layer may be used as a local charge trap layer. A flash memory may use a floating charge storage layer and a SONOS memory may use a charge trap layer.

Channel regions 160a, 160b may be formed around one or more surfaces of the upper portions of the outer side surfaces of the fins 105a, 105b and/or the upper surfaces of the fins 105a, 105b. The buried insulating layer 115 may be buried into the inner side surfaces of the fins 105a, 105b, and a channel may not be formed in the inner side surfaces of the fins 105a and 105b. However, with respect to relative area, a main conductive path for charges may be channel regions 160a, 160b formed on the outer side surfaces of the fins 105a, 105b.

By controlling a height of the fins 105a, 105b, for example, a height of the upper portions of the fins 105a, 105b exposed by the isolation layer 120, the area of the channel regions 160a, 160b may be controlled. Therefore, using the channel regions 160a, 160b formed in the fins 105a, 105b, an operation current of the non-volatile memory device 100, that is, a speed thereof may be increased, and thus, performance of the non-volatile memory device 100 may be improved.

At least one pair of a source region 145 and a drain region 150 may be formed at the fins 105a, 105b portions of both sides of the channel regions 160a, 160b. The source region 145 and the drain region 150 may be reversed. Adjacent channel regions 160a, 160b may share the source region 145 and the drain region 150. The source region 145 and the drain region 150 may form a diode-junction with the body 102 or rest fins 105a, 105b regions. For example, if the source region 145 and the drain region 150 are doped with n-type impurities, the rest fins 105a, 105b regions or the body 102 may be doped with p-type impurities.

The control gate electrodes 140 may surround the channel regions 160a, 160b and the buried insulating layer 115, and may be insulated from the body 102 by the isolation layer 120. That is, the control gate electrodes 140 may be formed to extend along the direction of X1, and may be spaced from each other along the direction of X2. The number of the control gate electrodes 140 does not limit the scope of example embodiments of the present invention. The control gate electrode 140 may be composed of polysilicon, metal, metal silicide, or a combination layer thereof.

Although not shown in the drawing, the non-volatile memory device 100 may further include a blocking insulating layer between the control gate electrode 140 and the storage nodes 130a, 130b. For example, if the storage nodes 130a, 130b are composed of a conductive material, for example, polysilicon or silicon-germanium, a blocking insulating layer may be used. For example, the blocking insulating layer may be formed of a silicon oxide layer.

With respect to operation characteristics of the non-volatile memory device 100, the channel regions 160a, 160b formed in the fins 105a, 105b, and a depletion region of the source region 145 and the drain region 150 may be limited. For example, as the fins 105a, 105b are thinner in width, the depletion region may be further limited.

For example, the depletion region may be limited in the width direction of the fins 105a, 105b, that is, the direction of X1, but may be formed along the direction of X3. However, as the width of the fins 105a, 105b is reduced, the influence of the depletion region formed along the direction of X3 may be decreased.

Thus, even though the fins 105a, 105b are connected to the body 102, the fins 105a, 105b become a structure similar to an SOI structure, that is, SOI-like structure. Thus, off-current and junction leakage current, which may be generated by extension of the depletion region, may be reduced. Further, by applying a voltage to the body 102, an advantage of applying a body bias to the fins 105a, 105b may be maintained.

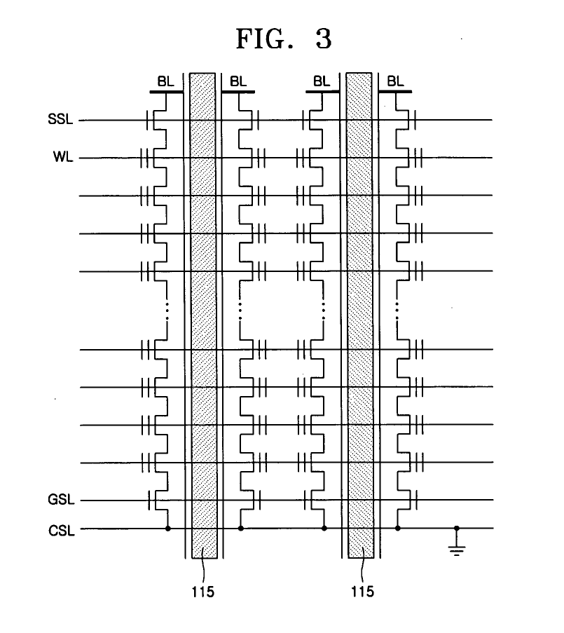

An example circuit layout of the non-volatile memory device 100 of the present invention is illustrated in FIG. 3. Referring to FIGS. 1 through 3, the non-volatile memory device 100 may be a NAND structure flash memory or a SONOS memory. The control gate electrodes 140 may be used as a word line WL, and the fins 105a, 105b may be used as a bit line BL. For example, the source region 145 and the drain region 150 of the fins 105a, 105b may be connected to a bit line BL. The number of the word lines WL may be determined in accordance with a unit of one NAND cell. A pair of NAND cells may be insulated from each other by the buried insulating layer 115. The bit line BL may be connected to the word lines WL via a string select line (SSL), and may be connected to the grounded Common Source Line (CSL) via a ground select line (GSL). Thus, by turning on the SSL and the GSL, and selecting one bit line BL, it is possible to access to the NAND cell disposed in one line. Specific operation of the NAND cell is well known to those skilled in the art, and detailed description thereof will be omitted.

In an example embodiment, a gate length W1 of the control gate electrode 140 may be 1 F, a width W2 of the fins 105a, 105b may be 0.25 F, and a width W3 of the buried insulating layer 115 may be 0.5 F. A width W4 of the isolation layer 120 adjacent to the outer side surface of each of the fins 105a, 105b constituting a pair of NAND cells may be 0.5 F. Thus, a length of the pair of the NAND cells may be 2 F based on the direction of the word line WL, that is, in the direction of X1. Further, a separation distance W5 of the control gate electrodes 140 may be 1 F. Thus, a length of one unit cell including one control gate electrode 140 may be 2 F based on the direction of the bit line BL, that is, the direction of X2. A pair of unit cells may be connected in the direction of X2, thereby forming a pair of NAND cell structures.

Thus, one word line WL and two bit lines BL may be included in the area of 2 F×2 F. That is, one pair of unit cells may be formed in the area of 2 F×2 F. Thus, as compared to the conventional case where one unit cell is formed in the area of 2 F×2 F, a non-volatile memory device in accordance with example embodiments of the present invention may increase an integration density of unit cells by a factor of two. That is, a pair of NAND cells separated by the buried insulating layer 115 may occupy the same area as that of one conventional NAND cell. Thus, in the case that one NAND cell operates in a single level cell (SLC) manner storing one single bit, the area of 2 F×2 F is necessary to make two bits, and the area per bit may be 2 F². As another example, in the case that one NAND cell operates in a multi level cell (MLC) manner storing two bits, the area of 2 F×2 F is necessary to make four bits, and the area per bit may be 1 F².

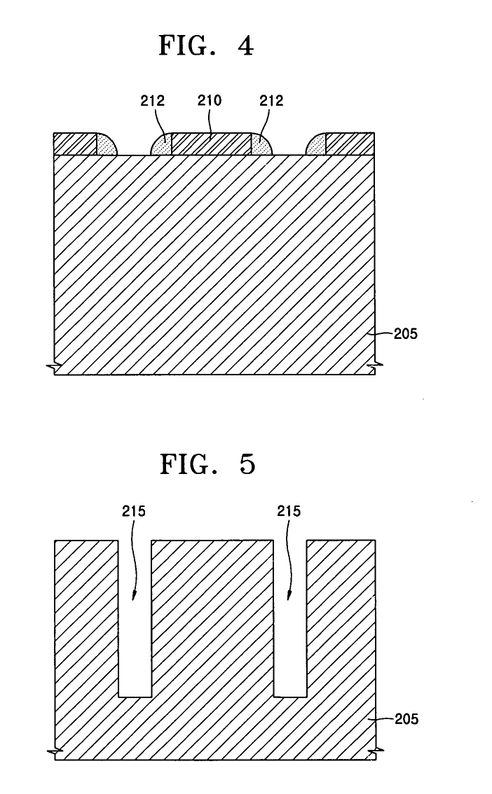

FIGS. 4 through 11 are sectional views illustrating a method of fabricating a non-volatile memory device according to an example embodiment of the present invention. A structure of the non-volatile memory device according to an example method of the present invention may be illustrated in FIGS. 1 through 3. FIGS. 4 through 11 are sectional views taken along the direction of X1 of FIG. 1, that is, a line of I-I′ of FIG. 1.

Referring to FIG. 4, a first insulating layer pattern 210 may be formed on a semiconductor substrate 205, for example, bulk silicon. For example, the first insulating layer pattern 210 may be formed of a silicon oxide layer. A second insulating layer spacer 212 may be formed on the sidewalls of the first insulating layer pattern 210. For example, the second insulating layer spacer 212 may be a silicon nitride layer. For example, the second insulating layer spacer 212 may be formed by forming a second insulating layer (not shown) and anisotropically etching the second insulating layer.

Referring to FIG. 5, the semiconductor substrate 205 may be etched using the first insulating layer pattern 210 (FIG. 4) and the second insulating layer pattern 212 (FIG. 4) as an etch protecting mask, thereby forming first trenches 215. For example, the first trenches 215 may be formed with a width of 0.5 F based on the length of a gate of a control gate electrode 250 (FIG. 11) to be formed later. For example, the gate length of the control gate electrode 250 (FIG. 11) may be 1 F. The first insulating layer pattern 210 and the second insulating layer spacer 212 may be removed.

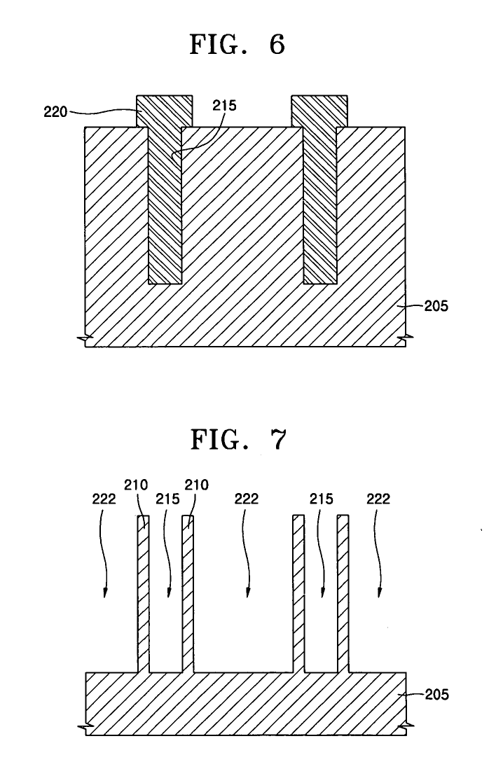

Referring to FIG. 6, a first photoresist pattern 220 may be formed to bury the first trench 215 and extend to the semiconductor substrate 205 as much as a desired or predetermined width in both directions of the first trench 215. For example, the first photoresist pattern 220 may be formed by forming a photoresist layer (not shown) on the overall surface of the resultant structure having the first trench 215, and patterning the photoresist layer using a photolithography and etch technique.

Referring to FIG. 7, the semiconductor substrate 205 may be etched using the first photoresist pattern 220 (FIG. 6) as an etch protecting mask, thereby forming second trenches 222. The first photoresist pattern 220 (FIG. 6) may be removed, thereby forming at least one pair of fins 210 defining the first and second trenches 215, 222 and protruding from the semiconductor substrate 205. A width of the fin 210 may be determined by a width of the first photoresist pattern 220 (FIG. 6) extending onto the semiconductor substrate 205. For example, a width of the fin 210 may be 0.25 F.

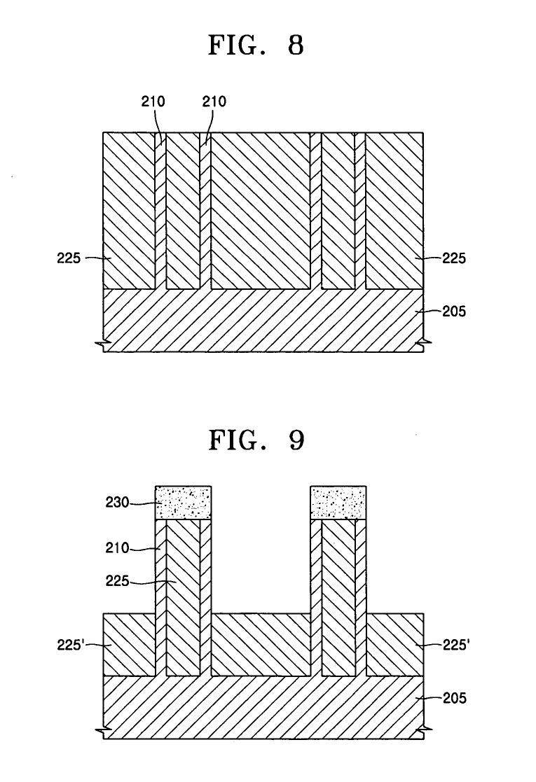

Referring to FIG. 8, a third insulating layer 225 burying the first and second trenches 215, 222 (FIG. 7) may be formed. For example, the third insulating layer 225 may be formed by depositing a silicon oxide layer on the overall surface of the resultant structure having the fins 210, and planarizing the silicon oxide layer until the fins 210 are exposed. The planarization may be performed using an etch back process or a chemical mechanical polishing process.

Referring to FIG. 9, the third insulating layer 225 burying the second trench 222 (FIG. 7) may be selectively etched by a desired or predetermined depth. For example, a second photoresist pattern 230 may be formed to cover the third insulating layer 225 burying the fins 210 and the first trench 215. The third insulating layer 225 may be etched using the second photoresist pattern 230 as an etch protecting mask. Thus, the outer side surfaces of the fins 210 may be exposed as much as a desired or predetermined height. That is, upper portions of the outer side surfaces of the fins 210 may be exposed, and lower portions of the fins 210 are surrounded by the etched third insulating layer 225′. The second photoresist pattern 230 may be removed.

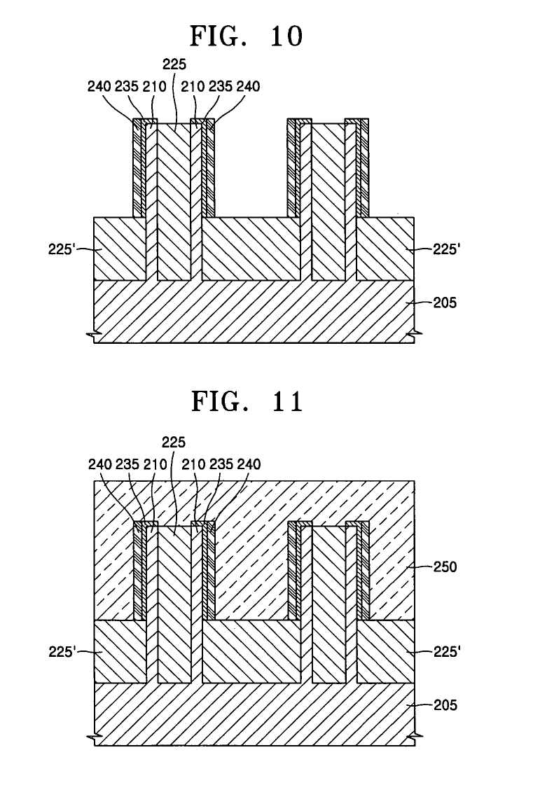

Referring to FIG. 10, a gate insulating layer 235 may be formed on the exposed upper portions of the outer side surfaces and the exposed upper surfaces of the fins 210 surrounding the third insulating layer 225. For example, the gate insulating layer 235 may be formed of a silicon oxide layer, a silicon nitride layer, a high-k dielectric layer, or a combination layer thereof. The gate insulating layer 235 may be formed by thermally oxidizing the fins 210, or depositing a material layer using a chemical vapor deposition (CVD) process.

Storage nodes 240 may be formed on the sidewalls of the gate insulating layer 235 formed on the exposed outer side surfaces of the fins 210. For example, the storage nodes 240 may be vertically formed on the semiconductor substrate 205. The storage nodes 240 may be formed to include polysilicon, silicon germanium, silicon or metal dot, nano crystal, or a silicon nitride layer.

Referring to FIG. 11, control gate electrodes 250 may be formed to run across the fins 210 and the third insulating layer 225 on the resultant structure having the storage nodes 240. The control gate electrode 250 may be formed by depositing a control gate electrode layer (not shown) and patterning the control gate electrode layer using a photolithography and etch technique. Before patterning the control gate electrode layer, a process of planarizing the control gate electrode layer may be further included. Further, before forming the control gate electrode 250, a blocking insulating layer (not shown) surrounding the storage nodes 240 may be further formed.

A separation distance of the control gate electrodes 250 may be 1 F. A pair of unit cells having one pair of storage nodes 240 separated by the third insulating layer 225 may be formed in the area of 2 F×2 F. Thus, the non-volatile memory device according to example embodiments of the present invention may have an integration density two times higher than that of a conventional device based on area per bit.

A non-volatile memory device according to example embodiments described as above may employ an SOI-like structure, and may decrease an off-current and/or a junction leakage current.

Although example embodiments of the present invention have been described as having a NAND structure, example embodiments of the present invention may also be directed to NOR structures.

Although example embodiments of forming the fins have been described above, any other technique for forming the fins from a semiconductor substrate body may also be used.

While the present invention has been particularly shown and described with reference to example embodiments thereof, it will be understood by those of ordinary skill in the art that various changes in form and details may be made therein without departing from the spirit and scope of the present invention as defined by the following claims.

What is claimed is:

1. A non-volatile memory device comprising:
a semiconductor substrate including a body and at least one pair of fins formed from and protruding from the body and extending along one direction spaced from each other.

2. The non-volatile memory device of claim 1, wherein the at least one pair of fins do not float in relation to the body.

3. The non-volatile memory device of claim 1, wherein the non-volatile memory device is a flash memory.

4. The non-volatile memory device of claim 1, wherein the non-volatile memory device is a Semiconductor Oxide Nitride Oxide Semiconductor (SONOS) memory.

5. The non-volatile memory device of claim 1, wherein the non-volatile memory device has a NAND structure.

6. The non-volatile memory device of claim 1, wherein the non-volatile memory device has a NOR structure.

7. The non-volatile memory device of claim 1, further comprising:
at least one pair of channel regions formed around surfaces of at least upper portions of outer side surfaces of the at least one pair of fins and upper surfaces of the at least one pair of fins;
at least one control gate electrode extending along a direction different from the one direction, and insulated from the semiconductor substrate; and
at least one pair of storage nodes interposed between the at least one control gate electrode and the at least one pair of channel regions formed on the upper portions of the outer side surfaces of the at least one pair of fins.

8. The non-volatile memory device according to claim 7, wherein the at least one pair of storage nodes includes polysilicon, silicon germanium, silicon or metal dot, nano crystal, or a silicon nitride layer.

9. The non-volatile memory device according to claim 7, wherein a gate length of the at least one control gate electrodes along the one direction is 1 F and a width of each fin of the at least one pair of fins along the different direction is 0.25 F.

10. The non-volatile memory device according to claim 7, wherein the at least one pair of fins operate as bit lines and the at least one control gate electrode operate as a word line.

11. The non-volatile memory device of claim 7, further comprising:
a first insulating layer formed on the body and burying portions between the at least one pair of fins;
at least one pair of source and drain regions spaced from each other along the one direction, and formed in the at least one pair of fins;
wherein the at least one pair of channel regions are disposed between the at least one pair of source and drain regions; and
a second insulating layer formed on the at least one pair of channel regions;
wherein the at least one control gate electrode extends across the first insulating layer and the second insulating layer.

12. The non-volatile memory device according to claim 11, further comprising a third insulating layer formed to expose lower portions of the outer side surfaces of the at least one pair of fins, and upper portions of the outer side surfaces of the at least one pair of fins on the body, and insulating the body and the control gate electrode.

13. The non-volatile memory device according to claim 11, wherein a width of the first insulating layer along the different direction is 1 F.

14. The non-volatile memory device according to claim 11, wherein the first insulating layer comprises a silicon oxide layer.

15. The non-volatile memory device according to claim 5, wherein the at least one pair of fins operates as at least one pair of bit lines, the non-volatile memory device further comprising:
a first insulating layer burying portions between the at least one pair of fins and the body to insulate the at least one pair of bit lines;
a plurality of word lines, extending across the at least one pair of fins and spaced from each other along the one direction, composed of a plurality of control gate electrodes, insulated from the semiconductor substrate;
a second insulating layer interposed between the plurality of word lines and the at least one pair of fins; and
at least one pair of storage nodes interposed between the plurality of word lines and at least a portion of the second insulating layer.

16. The non-volatile memory device according to claim 15, wherein a gate length of the plurality of control gate electrodes along the one direction is 1 F, and a width of each fin of the at least one pair of fins along a different direction is 0.25 F.

17. The non-volatile memory device according to claim 15, wherein a width of the first insulating layer along a different direction is 1 F.

18. The non-volatile memory device according to claim 15, wherein a separation distance between each of the plurality of control gate electrodes along the one direction is 1 F.

19. The non-volatile memory device according to claim 15, wherein the at least one pair of storage nodes include polysilicon, silicon germanium, a silicon or metal dot, a nano crystal, or a silicon nitride layer.

20. The non-volatile memory device according to claim 15, wherein the first insulating layer comprises a silicon oxide layer.

21. A method of fabricating a non-volatile memory device comprising:
forming at least one pair of fins from a semiconductor substrate including a body, protruding from the body and extending along one direction spaced from each other.

22. The method of claim 21, wherein the at least one pair of fins do not float in relation to the body.

23. The method of claim 21, wherein the non-volatile memory device is a flash memory.

24. The method of claim 21, wherein the non-volatile memory device is a Semiconductor Oxide Nitride Oxide Semiconductor (SONOS) memory.

25. The method of claim 21, wherein the non-volatile memory device has a NAND structure.

26. The method of claim 21, wherein the non-volatile memory device has a NOR structure.

27. The method of claim 21, wherein forming the at least one pair of fins further includes:
forming a first insulating layer pattern on the semiconductor substrate;
forming a second insulating layer spacer on sidewalls of the first insulating layer pattern;
etching the semiconductor substrate using the first insulating layer pattern and the second insulating layer spacer as etch protecting mask, thereby forming a first trench;
forming a first photoresist pattern in the first trench and extending over the semiconductor substrate in at least two directions by a given width;
etching the semiconductor substrate using the first photoresist pattern as an etch protecting mask, thereby forming a second trench; and
removing the first photoresist pattern, thereby forming the at least one pair of fins defined by the first and second trenches and protruding from the semiconductor substrate.

28. The method according to claim 27, wherein a width of the first trench is 0.5 F and a width of the second trench is 1 F.

29. The method according to claim 27, wherein a width of each fin of the at least one pair of fins is 0.25 F.

30. The method of claim 27, wherein forming the non-volatile memory device further comprises:
forming a third insulating layer in the first and second trenches defining the at least one pair of fins;
selectively etching the third insulating layer in the second trench, thereby exposing outer side surfaces of the at least one pair of fins surrounding the third insulating layer in the first trench;
forming a gate insulating layer on exposed outer side surfaces and upper surfaces of the at least one pair of fins surrounding the third insulating layer;
forming storage nodes on sidewalls of the gate insulating layer formed on the exposed outer side surfaces of the at least one pair of fins; and
forming a control gate electrode across the at least one pair of fins and the third insulating layer on the resultant structure having the storage nodes.

31. The method according to claim 30, wherein etching the third insulating layer includes:
forming a second photoresist pattern on the third insulating layer in the fins and the first trench; and
etching the third insulating layer in the second trench, using the second photoresist pattern as an etch protecting mask.

32. The method according to claim 30, wherein a gate length of the control gate electrode is 1 F, a width of the first trench is 0.5 F, and a width of the second trench is 1 F.

33. The method according to claim 30, wherein the storage nodes include polysilicon, silicon germanium, silicon or metal dot, nano crystal, or a silicon nitride layer.

34. The method according to claim 30, wherein the third insulating layer comprises a silicon oxide layer.
